(19) United States
(12) Patent Application Publication
(10) Pub. No.: US 2004/0136847 A1
(43) Pub. Date: Jul. 15, 2004

(54) Motor-driven pump unit

(75) Inventors: Franz Arbogast, Heidenheim (DE); Gunther Nagel, Steinheim (DE)

Correspondence Address: Charles N.J. Ruggiero, Esq., Ohlandt, Greeley, Ruggiero & Perle, L.L.P., 10th Floor, One Landmark Square, Stamford, CT, 06901-2682, US

(73) Assignee: Voith Turbo GmbH & Co. KG

(21) Appl. No.: 10/693,435

(22) Filed: Oct. 24, 2003

(30) Foreign Application Priority Data
Oct. 24, 2002 (DE) 102 49 494.0-15

(51) Int. Cl. H02K 9/00; H01L 41/18; H01L 41/08

(52) U.S. Cl. 417/423.7; 310/58; 310/361; 417/423.15

(57) ABSTRACT

A motor-driven pump unit is provided having an electric motor comprising a stator, and a rotor, a pump, and a housing. The pump is concentrically enclosed by the rotor of the motor, and the rotor of the motor is U-shaped in an axial sectional view. The web of the U-shape is provided in the region of the common axis with internal gearing and the shaft of the pump has a pinion that mates with the internal gearing. The housing has a face wall on the web side and an opposite face on the connection side, which carries the connections for the medium to be conveyed. The housing can be arranged in the region of the face wall on the web side as a container for receiving the conveying medium or for receiving a cooling device or for receiving a filtering device. The housing can also be arranged as a valve block in the region of the face on the connection side, having at least one of the following devices: a directional control valve, a safety valve, a pressure reducing valve, a quantity divider, a flow control valve, a stop valve, and/or a proportional valve.

### CROSS-REFERENCE TO RELATED APPLICATIONS

This application is related to, and claims priority in, German Patent Application No. 102 49 494.0-15, filed on Oct. 24, 2002, the disclosure of which is incorporated in its entirety by reference herein.

### BACKGROUND OF THE INVENTION

1. Field of the Invention

The invention relates to a motor-driven pump unit in which an electric motor and a pump are constructionally combined with each other. The rotor/stator of the motor encloses the pump.

2. Description of the Prior Art

DE 195 38 278 A1 describes a motor-driven pump unit. The rotor of the electric motor is the impeller of the pump at the same time.

EP 0 611 887 A1 describes a motor-driven pump unit. Although the rotor of the motor is a separate component, it is torsionally rigidly connected with the cylinder block of a reciprocating pump.

PCT/EP01/03357 describes a motor-driven pump unit in which the rotor of the electric motor is pot-shaped. The rotor is situated between the stator of the motor and the pump. The rotor and the pump are in driving connection via a gearing.

This prior known unit comes with the advantage that it has a minimal diameter. The radial extension is thus relatively low.

There is a problem in the respect that mostly there is insufficient constructional space in the axial direction. A reduction in the length in the axial direction is not practical. In order to produce a certain power, the motor needs to have a certain axial length. An additional factor is that such a unit comprises numerous subassemblies such as valves, electricity charge dividers and a reservoir for the medium to be conveyed. These subassemblies increase the need for space in the axial direction.

### SUMMARY OF THE INVENTION

Against the foregoing background, it is a primary object of the present invention to provide a motor-driven pump unit having its axial dimension reduced without having to increase its radial dimension while maintaining the motor output and pump output.

The inventors have therefore integrated subassemblies of the kind mentioned above in the housing of the unit, namely in the region of the face wall of the housing. This allows making do with a lower amount of axial constructional space without having to increase the radial constructional space.

These and other objects and advantages of the present invention are provided by a motor-driven pump unit with an electric motor comprising a stator and a rotor. The pump unit also has a pump that is concentrically enclosed by the rotor of the motor. The rotor of the motor is U-shaped when seen in an axial sectional view. The web of the U is provided in the region of the common axis with an internal gearing. The shaft of the pump has a pinion which mates with the internal gearing of the web of the U. The pump unit also has a housing comprising a face wall on the web side and an opposite face on the connection side, which carries the connections for the medium to be conveyed. The pump unit can have the housing arranged in the region of the face wall on the web side as a container for receiving the conveying medium or for receiving a cooling device or for receiving a filtering device. The housing can also be arranged as a valve block in the region of the face on the connection side, and can comprise at least one of the following flow control devices: a directional control valve; a safety valve; a pressure reducing valve; a quantity divider; a flow control valve; a stop valve; and/or a proportional valve.

The rotor of the electric motor can enclose the pump housing and can be held on the same. The pump may be a hydraulic pump. At least a part of the throughput of the medium of the pump can be used for cooling the motor. The tank may be situated between the web of the U and the face wall of the housing on the web side. The shaft of the pump can project into the tank and can carry an impeller. The impeller may be configured and arranged in such a way that it conveys cooling medium out of the motor into the pump.

### BRIEF DESCRIPTION OF THE DRAWINGS

The foregoing, and still further objects and advantages of the present invention, will be more apparent from the following detailed explanation of the preferred embodiment of the invention in connection with the accompanying drawing:

FIG. 1 is a plan view of a motor-driven pump unit of the present invention.

### DESCRIPTION OF THE INVENTION

Referring to the drawing, there is provided a motor-driven pump unit generally represented by reference numeral 1. The pump unit 1 comprises an electric motor 10 with a stator core stack 11, a winding 12 and a rotor 13.

The pump unit 1 also comprises an internal gear pump 20. It comprises a pinion 21, a hollow wheel 22, which is eccentric relative to the same, and a pinion shaft 23. The pinion shaft 23 is held in side disks 24 and 25. Sliding bearings 241 and 251 are provided in the present invention.

The motor 10 and pump 20 are enclosed by a common housing 30. An inlet 34 is situated in the housing between the rotor 13 and the stator 11 for introducing coolant, as well as an outlet 35 leading axially out of the pump 20.

According to the present invention, the rotor 13 preferably has a pot-shaped arrangement. In the present axial section, the shape of rotor 13 appears U-shaped. The pinion shaft 23 is in rotational connection with the rotor 13 via gearing. In the web 131 of the U-shape, there is an internal gearing, whereas the pinion shaft 23 comprises a respective external gearing. The internal and external gearings mate with each other.

Alternatively, a different driving connection between the rotor 13 of motor 10 and the pinion shaft 23 could be used. It is possible to provide two or more gearings with respective torque-transmitting elements instead of only one single one, so that a transformation from the speed of the rotor 13 to the pinion shaft 23 occurs to either slow or fast. The rotor 13 is held on the pump 20 along the two side disks 24 and 25.

The housing 30 comprises a cylindrical, sleeve-like member 31, a side disk 32 located in the region of the web 131 of the U-shape as well as a side disk 33. A feed line 34 and a discharge line 35 for the substance or medium to be conveyed are incorporated in the side disk 33. The arrows indicate the direction of flow of the medium between the rotor 13 and stator 11 of the electric motor 10 and through the pump 20.

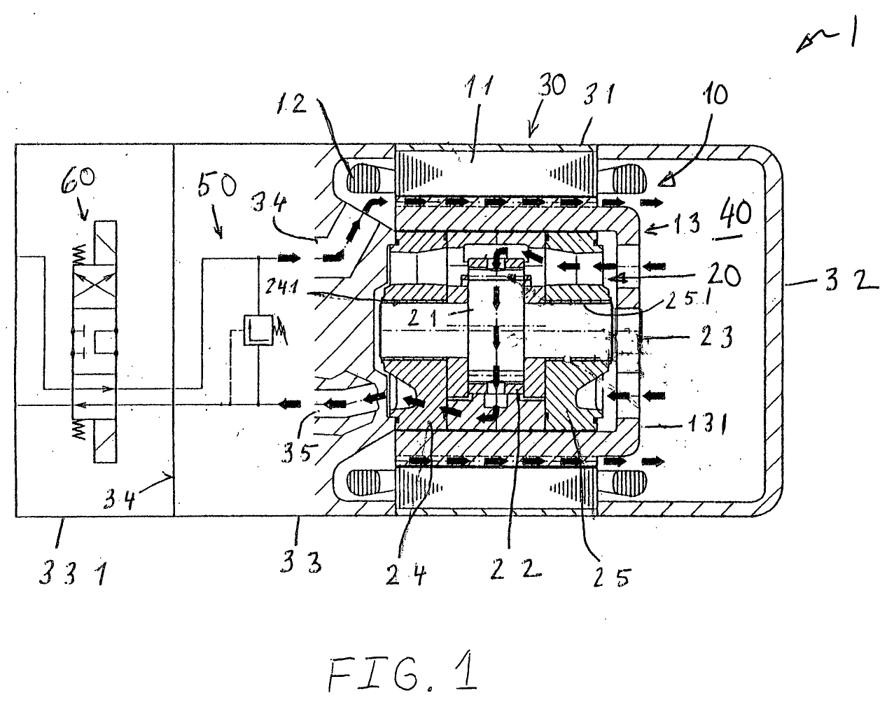

As is shown in FIG. 1, the cylindrical member 31 of the housing 30 is extended towards the side disk 32 on the web side, thus producing a relatively large space 40. Space 40 can be used as an oil tank, a container for receiving a cooling device and/or a container for receiving a filtering device.

The side disk 33 further contains a pressure control valve 50 and a directional control valve 60. The directional control valve 60 is arranged in a block or valve block 331. Block 331 is placed along a separating plane 34 on the main part of the side disk 33 and is connected with the main part and preferably rigidly connected, e.g., by a screwed connection. In the mounted state (as shown in FIG. 1), the lines of the block 331 and the main part of the side disk 33 are in alignment with each other, so that they are in conductive connection with each other. Valve block can comprise other flow control devices, such as, for example, a safety valve; a pressure reducing valve; a quantity divider; a flow control valve; a stop valve; a proportional valve; and combinations of these devices.

The present invention having been thus described with particular reference to the preferred forms thereof, it will be obvious that various changes and modifications may be made therein without departing from the spirit and scope of the present invention as defined in the appended claims.

What is claimed is:

1. A motor-driven pump unit comprising:
an electric motor having a stator and a rotor;
a pump being concentrically enclosed by said rotor, said rotor having a U-shape when viewed in an axial sectional view, wherein said U-shape has a web that is provided in the region of a common axis, said web having an internal gearing, and wherein said pump has a shaft that has a pinion that mates with said internal gearing of said web; and
a housing having a face wall on a web side and an opposite face on a connection side that carries connections for a medium to be conveyed, wherein said housing is arranged in a region of said face wall on said web side as a container for receiving said medium, for receiving a cooling device or for receiving a filtering device.

2. The motor-driven pump unit of claim 1, wherein said housing is arranged as a valve block in a region of said opposite face on said connection side, said valve block has a flow control device selected from the group consisting essentially of a directional control valve, a safety valve, a pressure reducing valve, a quantity divider, a flow control valve, a stop valve, a proportional valve, and any combinations thereof.

3. The motor-driven pump unit of claim 1, wherein said rotor encloses said pump and is operably connected to said housing.

4. The motor-driven pump unit of claim 1, wherein said pump is a hydraulic pump.

5. The motor-driven pump unit of claim 1, wherein said medium from said pump has a throughput with at least a portion thereof that is used for cooling said motor.

6. The motor-driven pump unit of claim 1, wherein said web of said U-shape and said face wall of said housing on said web side has therebetween a tank, wherein said shaft of said pump projects into said tank and carries an impeller, and wherein said impeller can convey cooling medium out of said motor into said pump.

7. A motor-driven pump unit comprising:
an electric motor having a stator and a rotor;
a pump being concentrically enclosed by said rotor, said rotor having a U-shape when viewed in an axial sectional view, wherein said U-shape has a web that is provided in the region of a common axis, said web having an internal gearing, wherein said pump has a shaft that has a pinion that mates with said internal gearing of said web; and
a housing having a face wall on a web side and an opposite face on a connection side that carries connections for a medium to be conveyed, wherein said housing is arranged as a valve block in a region of said opposite face on said connection side, and wherein said valve block has a flow control device selected from the group consisting essentially of a directional control valve, a safety valve, a pressure reducing valve, a quantity divider, a flow control valve, a stop valve, a proportional valve, and any combinations thereof.

8. The motor-driven pump unit of claim 7, wherein said rotor encloses said pump and is operably connected to said housing.

9. The motor-driven pump unit of claim 7, wherein said pump is a hydraulic pump.

10. The motor-driven pump unit as claimed in claim 7, wherein said medium from said pump has a throughput with at least a portion thereof that is used for cooling said motor.

11. The motor-driven pump unit of claim 7, wherein said web of said U-shape and said face wall of said housing on said web side has therebetween a tank, wherein said shaft of said pump projects into said tank and carries an impeller, and wherein said impeller can convey cooling medium out of said motor into said pump.
